(19) United States
(12) Patent Application Publication
(10) Pub. No.: US 2008/0156518 A1
(43) Pub. Date: Jul. 3, 2008

(54) Alignment and cutting of microelectronic substrates

(75) Inventors: Kenneth Allen Honer, Santa Clara, CA (US); Christopher Paul Wade, Los Gatos, CA (US); Seiichi Tobe, Tokyo (JP); Chung-Chuan Tseng, San Jose, CA (US); Ellis Chau, San Jose, CA (US); Kyong-Mo Bang, Sunnyvale, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/649,354

(22) Filed: Jan. 3, 2007

(51) Int. Cl. H05K 13/00; H01S 4/00; H05K 1/00

(52) U.S. Cl. 174/250; 29/592.1; 29/854

(57) ABSTRACT

A substrate including plural microelectronic device carriers has metallic alignment elements. The alignment elements desirably are disposed in a predetermined positional relationship to terminals on the carriers. The alignment elements are engaged with a carrier frame and a cutting device is aligned with the carrier frame. The cutting device cuts the carriers so that borders of the carriers are in a precise relationship with the terminals.

### FIELD OF THE INVENTION

The present invention relates to the cutting of individual chip carriers from a tape or substrate that is configured to hold a plurality of microelectronic devices.

### BACKGROUND OF THE INVENTION

In conventional methods for cutting out individual chip carriers from a tape or substrate having multiple chip carriers that have been manufactured commonly in a previous step, a substrate for holding multiple chips can be put into a punch index frame. The punch index frame is typically a rectangular frame with a rectangular opening in the middle configured to hold the substrate in the frame at a fixed position. The punch index frame can be positioned in X- and Y-directions parallel to the plane of the substrate by linear motion relative to a cutting tool. For positioning of the substrate in relation to the punch index frame, to guarantee that the substrate is cut at the right position, alignment holes are arranged on the punch index frame and on the substrate itself that match each other.

When cutting the substrate into individual chip carriers, it is desirable that the edges of the individual chip carriers are precisely defined relative to the connection terminals, for example package pins that are arranged on surfaces of the individual chip carriers.

However, the above alignment of the substrate relative to the frame has the disadvantage that the position of holes on the substrate can be imprecise or misaligned relative to the position of the package pins. Among other reasons, this misalignment is due to the formation of the holes by a separate process than the formation of the pins. This can lead to inaccuracy in the offset between the package pins and the outer periphery of the chip carriers.

Thus, there are substantial needs for improved methods with increased precision for cutting substrates or tapes into a plurality of chip carriers.

### SUMMARY OF THE INVENTION

One aspect of the present invention includes a method of cutting a substrate. The substrate has an upper and lower surface and the method cuts the substrate into individual microelectronic device carriers. Preferably, the method includes the steps of: inserting the substrate including a plurality of device carriers into a carrier frame by mechanically engaging at least one metallic alignment element with the carrier frame, and aligning a cutting device for cutting the substrate into individual device carriers with the carrier frame. The method also includes a step of cutting the substrate into the individual device carriers using the cutting device.

A second aspect of the present invention includes an in-process element for holding microelectronic devices. Preferably, the in-process element includes a substrate having an upper and lower surface and having a first area adapted to receive a plurality of microelectronic devices and a second area adapted for engagement with a carrier frame. The substrate includes metallic electrically conductive features in the first area of the substrate area configured for connection to microelectronic devices; and metallic alignment elements in the second area of the substrate, the metallic alignment elements being configured to mechanically engage into a carrier frame. Preferably, the metallic alignment elements are made from the same metal layer as the metallic conductive features, and are in predetermined positional relationship with the metallic conductive features.

### BRIEF DESCRIPTION OF THE DRAWINGS

These and other features, aspects and advantages of the present invention will become better understood with regard to the following description, appended claims and accompanying drawings were:

FIG. 1 is a sectional view of a stage in a method in accordance with a first embodiment of the present invention;

FIG. 2 is a top plan view of a stage in a method in accordance with the first embodiment of the present invention;

FIG. 3 is a sectional view of a later stage in a method in accordance with the first embodiment of the present invention;

FIG. 4 is a fragmentary sectional view of an enlarged scale of area A of the stage depicted in FIG. 3;

FIG. 5 is a sectional view of yet a later stage in a method in accordance with the first embodiment of the present invention;

FIG. 6 is a view similar to FIG. 3 but depicting elements in a method according to another embodiment of the present invention;

FIG. 7 is a close-up sectional view similar to FIG. 3 but depicting elements in a method according to yet another embodiment of the present invention;

FIG. 8 is a top plan view of a stage in a method in accordance with a another embodiment of the present invention;

FIG. 9 is a fragmentary sectional view along line CS2 of FIG. 8; and

FIG. 10 is a view similar to FIG. 3 but depicting elements in a method according to still another embodiment of the present invention.

It should be noted that the dimensions of the assemblies shown in the Figures may be distorted for clarity of the illustration, different proportions of the different dimensions are also possible, and like numbers represent similar elements.

### DETAILED DESCRIPTION

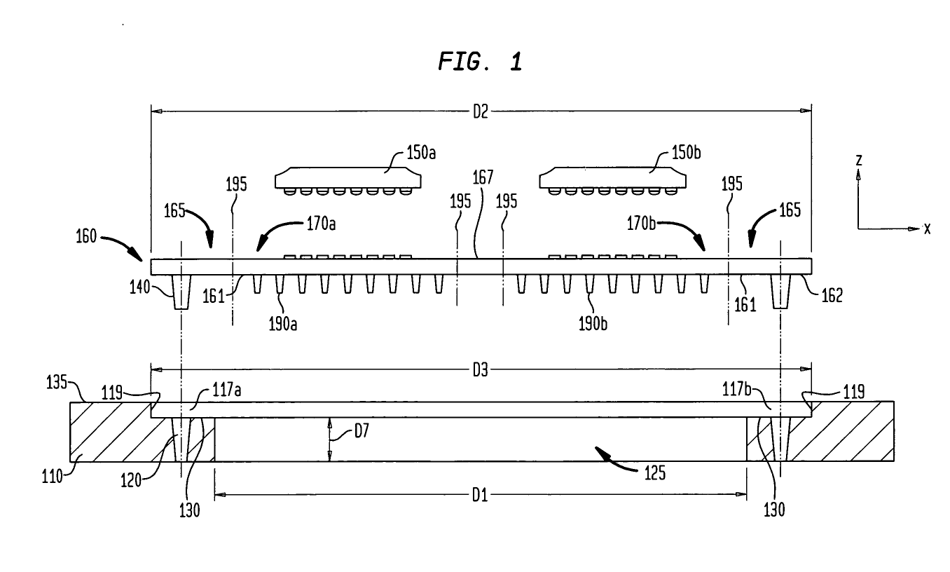

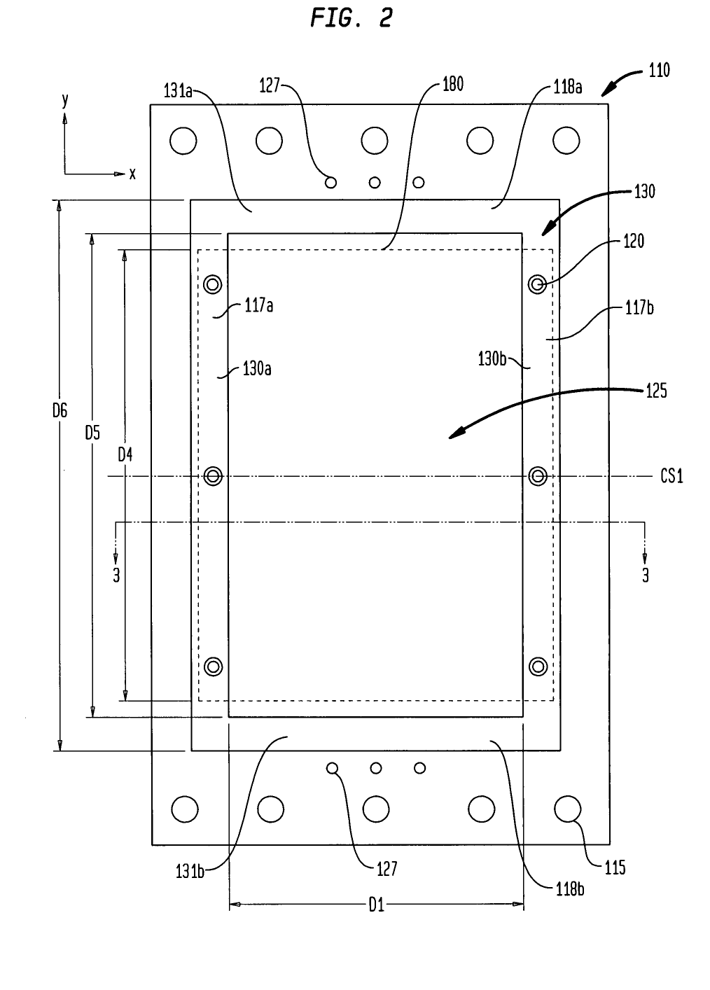

FIG. 1 schematically depicts a cross-sectional view of a stage of a method according to a first embodiment of the present invention. The cutting line CS1 of the cross-sectional view that is shown in FIG. 1 is indicated in FIG. 2. FIG. 1 shows an in-process element of a microelectronic device packaging and processing method, being a substrate or tape 160 that is to be mated and aligned with a frame 110. With reference to FIG. 1, an X-direction points to the right in parallel to the substrate 160, the Y-axis points away from the perspective of the viewer, while the Z-axis is indicated and points towards the top of FIG. 1. As used in this disclosure, terms such as “upwardly,” “upper,” “top,” “downwardly,” “lower,” “bottom,” “vertically,” and “horizontally” should be understood as referring to the frame of reference of the element specified, and need not conform to the normal gravitation frame of reference.

Frame 110 has an opening 125 with length D5 (FIG. 2) and width D1, that is smaller in at least the X-dimension (D1) or Y-dimension (D5) than the substrate 160, so that a substrate, when put on the upper surface 135 of the frame, will not tall through the opening 125. In the variant shown in FIG. 1, the width D1 of the opening 125 is smaller than the width D2 of the substrate 160 in the X-direction. Stated another way, at least one of the substrate's dimensions D2, D4 is wider than the dimensions of the opening D1, D5, respectively.

Frame 110 has recessed interior edges 110 forming support recesses 117a, 117b (FIG. 1), 118a and 118b (FIG. 2). These recesses form substantially rectangular cross-sections and are configured to accommodate at least a portion of an outer boundary area 165 of the substrate 160. The recesses 117a, 117b, 118a, and 118b have an interior vertical wall 119 (FIG. 1) extending upwardly in the Z direction and engagement surfaces 130a, 130b, 131a, and 131b, extending in an X-Y plane. As discussed below, the outer boundary 165 of substrate 160 will overlie at least some of the engagement surfaces 130a, 130b, 131a and 131b when the substrate is inserted into the frame 110. The width D3 (FIG. 1) across the two recesses 117a, 117b is greater than the width D2 of the substrate 160, so that the substrate 160 will fit into the recesses 117a, 117b. Likewise, the dimension D6 across recesses 118a, 118b is greater than the length D4 of the substrate (FIG. 2). The outline 180 of a substrate 160 that can be placed into the opening 125 and the recesses 117a, 117b, 118a and 118b of the carrier 110 is shown, indicated with dash-dotted lines. These lines are shown for the clarity of illustration, and may not be physically present on the frame 110.

In addition, frame 110 has first locating features in the form of holes 120 open to the engagement surfaces 130a and 130b. The axes of holes 120 are in the Z direction. In the variant shown, holes 120 are located substantially in the middle of engagement surfaces 130a, 130b. Six engagement holes 120 are depicted, but any number of engagement holes can be used. However, it is desirable that there are at least two holes arranged in opposite engagement surfaces 130a, and 130b, or 131a, and 131b of the carrier 110. Preferably, the holes 120 are located close to the corners of the outline 180 of the substrate 160. Frame 110 also has second location features 127, which in this embodiment are holes. The second location features 127 have a predetermined positional relationship with the first location features 120. Frame 110 further includes sprocket holes 115 that can be used for the movement and alignment of the carrier frame 110 towards a cutting device 210a, 210b (FIG. 5) in X and Y-direction.

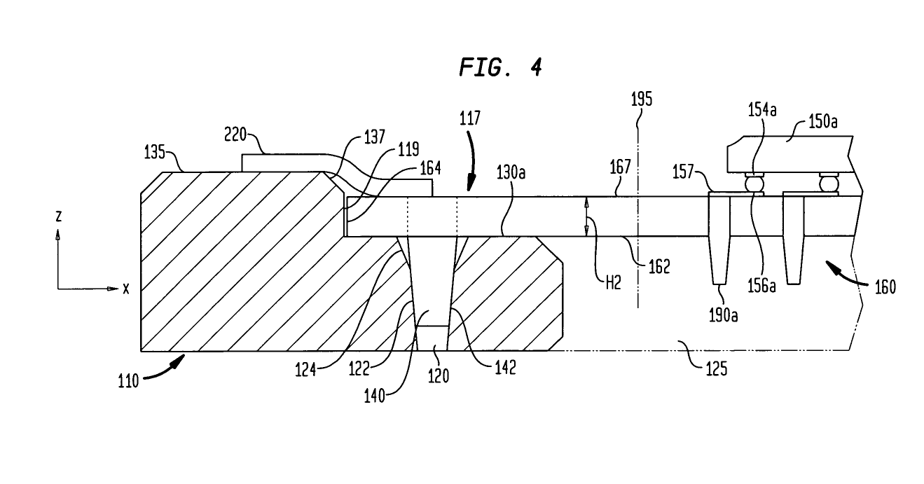

Substrate 160 includes a wiring panel made of at least one dielectric layer and conductive traces and terminals. As best seen in FIG. 4, the particular substrate 160 used in this embodiment has electrically conductive features including terminals in the form of pins 190a (FIG. 4) projecting from the bottom surface 162 of the dielectric layer. The substrate further includes traces 157 and bond pads 156a exposed at the top surface 167 of the dielectric layer. At least some of the bond pads 152a are electrically connected to at least some of the terminals or pins 190a by traces 157. The pins 190a, 190b will ultimately serve as electrical connection terminals for interconnection of the devices 150a, 150b with an outside device such as a wiring board. The conductive traces can be located on the top, bottom or inside the substrate. Other interconnection elements such as vias, posts, buried vias, etc. (not shown) can interconnect traces and terminals with each other. Examples of circuit panels having terminals in the form of posts and traces are disclosed in commonly-owned U.S. Pat. Nos. 6,782,610 and 6,826,827; and the U.S. Published Patent Application Nos. 20050116326 and 20050284658.

Substrate 160 includes a first area that will be used as chip carriers 170a, 170b, and a second area including outer boundary areas 165. The outer boundary areas 165 will partially or entirely overlie the frame surfaces 130a, 130b when the substrate 160 is engaged in the frame 110. The bottom surface 162 of the substrate 160 includes outer abutting surfaces 161 in outer boundary areas 165. Cutting lines 195 are depicted at the boundaries of the individual chip carriers 170a and 170b. The chip carriers 170a, 170b will form carriers for individual microelectronic devices 150a, 150b once cut out of the common substrate 160. The cutting lines 195 indicate the desired outer boundaries of the chip carriers 170a, 170b, and thus indicate the desired cutting location in a later step. The plurality of cutting lines 195 are shown in FIG. 1 as dash-dotted lines for illustration purposes only, and may not be physically present on the substrate 160. In the variant shown, the second or outer boundary areas 165 are disposable after cutting.

Substrate 160 further includes metallic alignment elements in the form of alignment posts 140. Posts 140 are desirably formed from the same metal layer or composite metal layer as metallic electrically conductive features such as terminal pins 190a, 190b of the chip carriers 170a, 170b. Therefore, the alignment features will be in a predetermined and precise positional relationship with respect to the metallic electrically conductive features. For example, in such a manufacturing step, an unitary metal structure including one or more metal layers is etched, and the metal other than the remaining metallic features such as engagement posts 140, terminal pins 190a, 190b, and traces 158a (FIG. 4) are etched away. The X-Y distance of the pins 190a, 190b to the engagement posts 140 is thereby defined within a very small tolerance. In other variants, alignment posts 140 are not made in the same manufacturing step of the pins 190a, 190b, but are manufactured in a controlled manner to ensure defined and precise X-Y location towards each other.

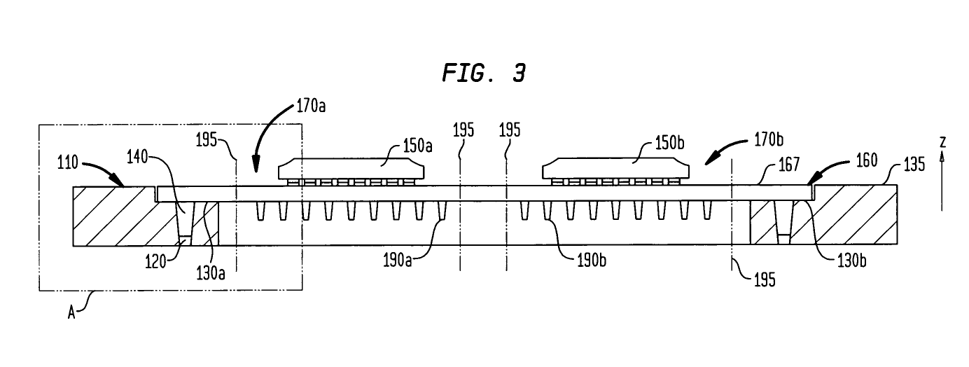

In one stage of a method according to an embodiment of the invention, substrate 160 is assembled with frame 110 as shown in FIGS. 3 and 4. In the assembled condition, surface portions 161 of the bottom surface of substrate 160 abut the surfaces 130a, 130b of the frame 110. In addition, the alignment features or posts 140 on the substrate are engaged in the first engagement features or holes 120 of frame 110. Since the posts 140 together with holes 120 define a precise mechanical connection with each other, and the mechanical tolerances are set precisely, the location of the conductive features or pins 190a, 190b relative to the frame is also precisely defined. The pins 190a, 190b of the chip carriers 170a, 170b are now located in the opening 125. In this variant, upper surface 135 of the frame 110 is substantially flush with the upper surface 167 of the substrate 160. Holes 120 fully traverse the frame 110, and the posts 140 engaged into the holes 120 are shorter than the length D7 of the holes.

FIG. 4 shows a fragmentary view of the area A of FIG. 3. While the holes 120 formed in the frame have frusto-conical shapes, the posts 140 have corresponding frusto-conical shapes, being complementary to each other. The holes 120 and the posts 140 have tight mechanical tolerances to each other. For example, the radial clearance between the post 140 and the hole 120 may be 25 microns or less. In addition, an upper portion of the inner walls 124 may be beveled and may have a smaller slope than the lower portion of the inner walls 122. The slope of the lower portion 122 of the inner walls may be equal to the slope of the taper of the engagement posts 140. The upper beveled portion helps engagement of the posts 140 into the corresponding holes 120.

The outer surface edge 164 of the substrate 160 is arranged close to the vertical wall 119 of the recesses 117a, 117b with a gap therebetween. The gap between the walls 119 and 164 should be bigger than the gap between the walls 122, 142 of the metallic alignment elements 140, 120. Stated another way, despite any tolerance of the placement of the wall 119 relative to pins 190a, 190b, wall 119 does not engage edge 164 of the substrate. In this variant, the Z-axis location of the upper surface 135 of the frame 110 is higher than the upper surface of the substrate 167. For facilitating the insertion of the substrate 160 into the openings 125 and recessed openings 117a, 117b, the inner edges 137 of the frame 110 are tapered. After engagement of the posts 140 into the holes 120, the substrate 160 optionally may be temporarily attached to the frame 110 by means of an adhesive tape 220. This temporary attachment can be done so as to avoid displacement of the substrate 160 out of the frame 110 during subsequent operations.

Before or after assembling substrate 160 with frame 110, microelectronic device 150 is mounted on the chip carriers 170 of substrate 160 and connected to bond pads 156a. The microelectronic devices 150a, 150b are preferably attached by means of soldering material 152a, 152b to bond pads 156a (FIG. 4).

In another stage of the method, frame 110 is inserted into a holder 242 of a cutting machine, and fastened by an upper clamp 240 to the holder. The holder 242 is in predetermined spatial relationship to the operative elements of the cutting machine. Alignment features such as pins(not shown) of holder 242 will engage with second location features 127 (FIG. 2) of the frame 110.

After engaging the frame 110 with holder 242, the cutting process for singulation of the chip carriers 170a, 170b is initiated. The particular cutting machine depicted in FIG. 5 uses a punch 210 punch and die 230. Die 230 engages the bottom surface 162 of the substrate. Blades 210a and 210b of the punch are forced through the substrate 160 at high speed in the negative Z-direction (downwardly as seen in FIG. 5). Blades 210a, 210b cut the substrate 160 to sever the individual chip carriers 170a, 170b from the remainder of the substrate.

As noted above, the substrate's alignment with respect to the carrier 110 is made with the metallic alignment features or posts 140 that were formed in close precision to pins 190a, and 190b. In addition, the carrier 110 is precisely positioned with respect to holder 242 that engages with second location features 127. Accordingly, the operative elements of the cutting machine, in this case cutting blades 210a, 210b, will be in precise relationship with the location of the pins 190a, 190b. The cutting machine will cut the substrate along cutting planes 195 which lie in precise positional relationship to the electrically conductive features or terminal pins 190a. After the cutting operation, each individual chip carrier will have edges lying in precise positional relationship with the conductive features or terminal pins 190a on that chip carrier. In use, the individual chip carriers 170 typically are mounted to a larger circuit panel as, for example, by solder-bonding the terminal pins 190a to corresponding pads on the circuit board. Because the edges of the chip carrier are in precise positional relationship to the terminal pins, the edges of the chip carrier will be precisely positioned relative to the pads of the circuit board. This precision avoids possible interference between edges of adjacent chip carriers which are placed close to one another on the circuit board. Stated another way, this precision allows the circuit board designer to place the pads for receiving one chip carrier closer to the pads for receiving an adjacent chip carrier, and allows closer packing of chip carriers on a circuit board. There is no need for additional optical alignment of the substrate 160 relative to the cutting machine.

The punch and die cutting apparatus depicted in FIG. 5 is merely exemplary. The cutting machine may include any type of cutting element capable of severing the chip carrier. For example, cutting element may be a knife or roller which moves along a predetermined path in the X and Y-directions to sever the chip carriers. In such a variant, engagement of the frame with the holding device of the cutting machine will precisely position the frame, and hence the substrate, with respect to the path of the cutting element. Likewise, the cutting element may be a laser, a waterjet cutting nozzle, a rotative saw blade, or other means that can be used to cut a substrate.

As discussed above, the microelectronic devices 150 may be mounted on the substrate before or after substrate 160 is mounted on frame 110. If the substrate is mounted on frame 110 before the microelectronic devices are mounted, the frame can used to hold the substrate in precise registration with the equipment used to mount the substrate, in the same way as the frame registers the substrate with the cutting equipment. In some cases, additional operations can be performed after the devices are mounted on the substrate but before cutting. For example, an encapsulant or underfill may be deposited around each device, and each device may be marked with identifying indicia. Here again, if the substrate is mounted on the frame before these operations, the frame can be used to register the devices and substrate relative to the tools used in these operations. The configuration of the second engagement features which register the frame 110 with the holder 242 can be varied. For example, sprocket holes 150 (FIG. 2) can be used as the second engagement features instead of the second engagement features or holes 127 discussed above.

A frame 310 used in a further embodiment of the invention is a substantially flat sheet of metal with an opening 325 to accommodate the conductive features of the substrate. In this embodiment, the engagement surface 330a of the frame is simply a portion of the top surface 335 of the frame. Stated another way, the frame omits the recess 117a, 117b, 118a, 118b (FIGS. 1 and 2) used in the embodiment discussed above. Frame 310 has first engagement features in the form of holes 320. In addition, the alignment features of the substrate include posts 340 having substantially a cylindrical shape and an outer surface 342. The lower edges 344 are beveled for easy engagement into holes 320. In this variant, the cross-sectional shape of the posts 340 is round, but other shapes are also possible, such as oval shapes, rectangular, or any polygonal shape, as long as the hole has a complementary cross-sectional shape allowing engagement of the corresponding post. In this embodiment, the second engagement features of the frame consist of the edges 302 of the frame. Thus, when the frame is engaged in the cutting machine or other fixture, the frame is located relative to the machine or fixture by engagement between the machine or fixture and the edges of the frame. In this embodiment, edges 302 should be formed in precise positional relationship to the first engagement features or holes 320.

It is not necessary that the chip carriers 370 have pins that project from the lower surface of the substrate. For example, the metallic electrically conductive features can also be flat or block shaped terminals, as long as the alignment features of the substrate, such as engagement posts 340, and metallic electrically conductive features of the chip carriers have a precisely defined positional relationship to each other.

In another variant, one of the posts 340 can be formed longer than all other posts of the substrate. The longer post preferably can be formed close to a corner of the substrate 360. The longer post may have a larger diameter than the remaining posts. The longer post may be inserted into the corresponding hole of the frame in a first step. In a subsequent step, the substrate 360 can be rotated in clockwise or counterclockwise around the Z-axis of the long post, to insert all the remaining posts 340 into their corresponding holes.

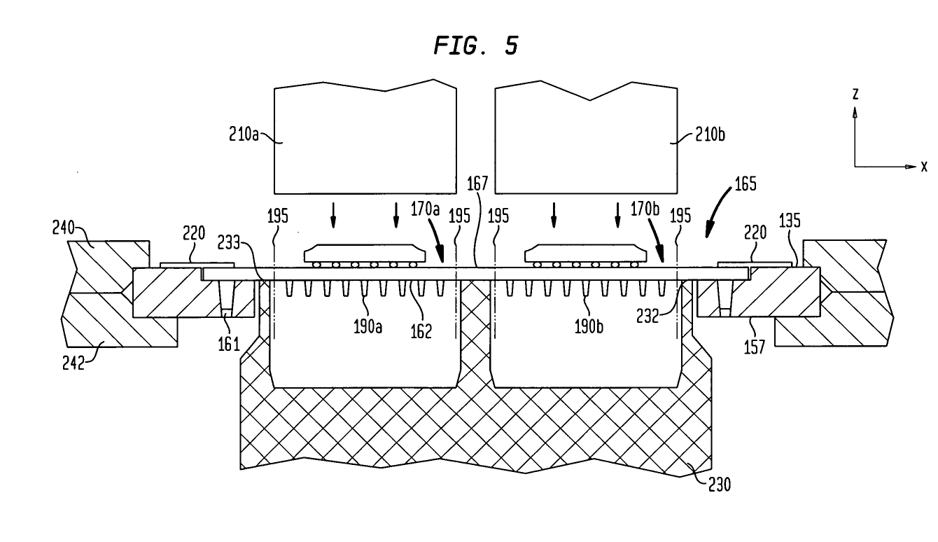

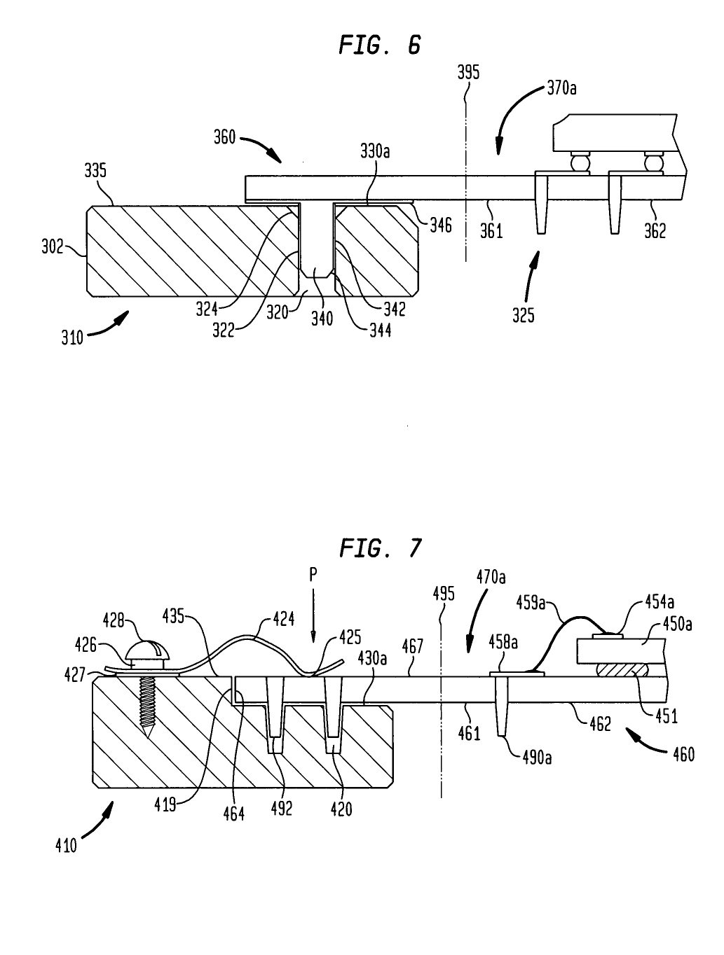

In FIG. 6, holes 320 extend entirely through the frame 310, but it is also possible to have holes which do not extend entirely through the frame, as long as the holes are deep enough to accommodate the posts 340. The diameter of the holes 320 desirably is just slightly bigger than the diameter the posts 340. For example, the diametrical clearance or difference between the diameter of the hole and diameter of the post may be about 5 to about 25 microns.

An additional feature of the alignment means of FIG. 6 is a metallic plate 346, formed on the bottom surface 362 of the substrate, contiguous with the post 340. The alignment plate 346 can substantially cover the engagement surface 330a of the frame 310, when the substrate is placed into the frame 310.

Alternatively, the plates 342 can be metal strips that substantially cover the surface 330a in the X-direction. The metallic plate 346 defines the Z-axis location of the substrate when put into the frame 310 with an increased precision, since dielectric layers of the substrate usually have less precision tolerances of surfaces compared to metallic features of the substrate. In another alternative, the metallic plate 346 extends beyond the cutting lines 395 into the area of the chip carrier 370a. The metallic plate may be connected with a ground or power supply terminal of each chip carrier. Such mechanical connection with metal elements could be desirable to further increase alignment precision of the substrate 360. In the cutting step, the plate would be severed to form an individual ground or power supply plane on each chip carrier 370a.

FIG. 7 shows another embodiment of the alignment features. In this embodiment, the upper surface 435 of the frame 410 is substantially flush to the upper surface of the substrate 460, when the substrate is placed into the frame 410. The alignment features of the substrate include one or more pins 492. The pins 492 for alignment are substantially the same size as the pins 490a of the chip carriers 470. In this variant, pins 492, formed by the same process as pins 490a, can be dummy or sacrificial pins that will be cut off from the substrate 460 when the substrate is severed along the cutting lines 495. Alternatively, pins 492 can be active pins, for example test pins that are connected to traces (not shown) leading into the areas of the substrate 460 constituting the chip carriers 470. The test pins preferably are used to test the substrate or the microelectronic devices 450, before the substrate is severed into separate chip carriers.

In the variant of FIG. 7 the temporary attachment of the substrate 460 to the frame 410 is done by a leaf spring 424 that is mounted to the upper surface 435 of the frame 410 by an attachment means, such as a screw 428 or a rivet. Leaf spring 424 is rotatable around the Z-axis defined by the middle axis of screw 428. The leaf spring 424 can be manually turned onto the substrate's upper surface 467, after the substrate is placed onto the frame, and the engagement pins 492 are placed into the corresponding holes 420. In an alternative embodiment, clamps pressing against the upper surface 467 of the substrate and the lower surface 457 of the frame can be used for fastening the substrate 460 to the frame 410.

In the variant of FIG. 7, microelectronic device 450 has connection pads 454a which are wire-bonded to terminals of the traces 458a by a bonding wire 459a. An adhesive 451 is used to stick the device 450a to the substrate. Any other system for mounting and connecting a chip to a substrate can be used.

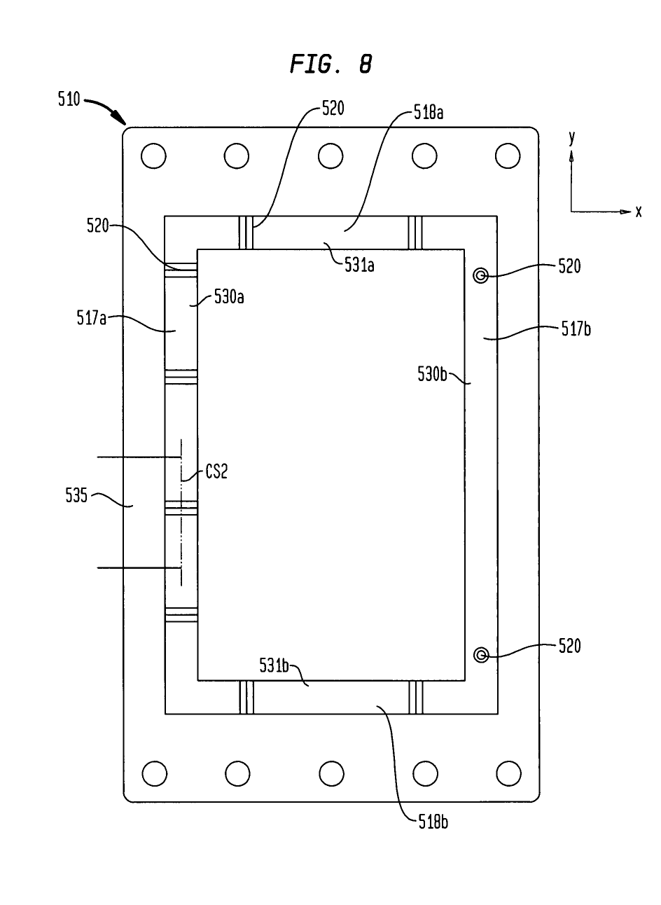

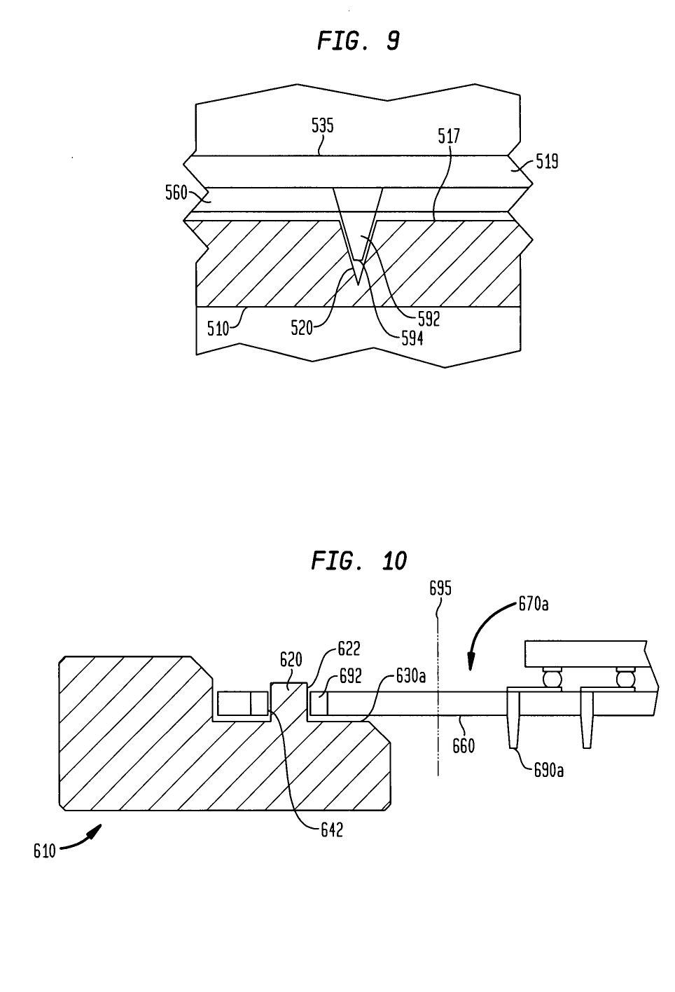

The alignment features of the present invention are not limited to posts that engage into corresponding holes. FIGS. 8 and 9 depict another embodiment, in which the first engagement features of the frame include grooves rather than holes. Grooves 520, 521 are arranged in the surfaces 530a, 531a, and 531b of the frame 510, respectively. Grooves 520, 521 engage with alignment features in the form of linear ridges 592 (FIG. 9) on the substrate. Four grooves 520 are arranged on one surface 530b, grooves 521 are arranged in surfaces 531a, 531b. Grooves 520 extend in the X-direction, whereas grooves 521 extend in the Y-direction, transverse to grooves 520. The alignment features or ridges 592 on the substrate which will mate with grooves 520 extend in the X-direction, whereas the ridges 592 which will mate with grooves 521 extend in the Y-direction. Here again, the alignment features are formed in precise positional relationship to the conductive features of the substrate. When the ridges of the substrate are engaged in the grooves, grooves 520 locate the substrate relative to the frame in the Y-direction, whereas grooves 521 locate the substrate relative to the frame in the X-direction. Optionally, one or more first engagement features in the form of holes 520, and a mating alignment feature in the form of a post or pin on the substrate, can be used in combination with one or more grooves. For example, it is possible to have only one hole 520 on one of the surfaces 530a, 530b, 531a, and 531b, preferably close to a corner of the frame 510, so that the substrate 560 can be inserted into the frame 510 by first engaging a post into hole 520, and subsequently can be rotated around the Z-axis, so as to engage ridges 592 (FIG. 9) into corresponding grooves 520. It is also possible to have no posts engaging in holes 520 at all, and to have only ridges engaging in grooves.

The ridges 592 (FIG. 9) have a blunted tip 594, but in alternative embodiments other cross-sections of the ridges are also possible, as long as they can be engaged into corresponding grooves 520 having a complementary cross-sectional shape. The cross-sectional shape of the groove 520 is a simple V cut into the upper surface 530a of the opening 517a. Alternatively, the grooves 520 may entirely traverse the frame 510.

FIG. 10 depicts another embodiment of the metallic alignment elements. A metallic ring 692 is formed that is embedded in the substrate 660. The metallic ring 692 is desirably formed from the same metal layer or composite metal layer as the pins 690a of the chip carrier 670a. The first engagement features of the frame 610 are posts 620 that project from the surface 630a. The dimensions of the post 620 are designed to fit into the ring 622. In the variant shown, posts 620 are made from the same material as the frame 610, but it is also possible that the posts 620 are made of a different material. Precise tolerances between inner wall 642 of the hole of the metallic ring 692 and the outer wall 622 of the post 620 permit high alignment precision of the posts 690a towards the frame 610. The gap between wall 622 and 642 can be in the same range as the gap between 122 and 142 shown with reference to FIG. 4.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

A substrate such as a flexible circuit panel which includes a plurality of chip carriers is aligned with a carrier frame by engaging metallic alignment elements carried on the substrate, such as metal posts, with features of the carrier frame. The carrier frame is aligned with a cutting device, for example by engaging features of the carrier frame with the cutting device. The metallic alignment elements and terminals on the chip carriers may be formed in the same process step, so that the terminals are in a precise positional relationship to the alignment features. The cutting device cuts the substrate to yield individual chip carriers having edges in precise positional relationship to the terminals.

As these and other variations and combinations of the features discussed herein can be utilized without departing from the present invention, the foregoing description of the preferred embodiments should be taken by way of illustration rather than by way of limitation of the invention as defined by the claims.

1. A method of cutting a substrate into individual microelectronic device carriers, comprising the steps of:
inserting a substrate including a plurality of device carriers into a carrier frame by mechanically engaging one or more metallic alignment elements on the substrate with the carrier frame;
aligning a cutting device with the carrier frame; and
cutting the substrate into the individual device carriers using the cutting device.

2. The method according to claim 1, wherein the cutting step further includes separating one or more areas of the substrate having the alignment elements from the individual device carriers.

3. The method according to claim 1, wherein the step of inserting further includes:
mating a portion of the substrate having the at least one metallic alignment elements with an engagement surface of the carrier frame.

4. The method according to claim 1, wherein the substrate has metallic electrically conductive terminals and the metallic alignment elements are disposed in a predetermined positional relationship to the terminals.

5. The method according to claim 4 wherein the metallic alignment elements and metallic terminals on the substrate are features which were formed from the same metal layer.

6. The method according to claim 5 wherein the terminals are pins projecting from a bottom surface of the substrate.

7. The method according to claim 6 wherein the alignment elements include posts projecting from the bottom surface of the substrate.

8. The method of cutting according to claim 1, wherein the step of inserting further includes:
rotating the substrate around one of the metallic alignment element, the one metallic alignment element being engaged into a locating feature of the carrier frame; and
engaging remaining ones of the metallic alignment elements with remaining locating features.

9. An in-process element for holding microelectronic devices comprising:
a substrate having an upper and lower surface and having a first area adapted to receive a plurality of microelectronic devices and a second area adapted for engagement with a carrier frame;
metallic electrically conductive features in the first area of the substrate area configured for connection to microelectronic devices; and
metallic alignment elements in the second area of the substrate, said metallic alignment elements being configured to mechanically engage into a carrier frame,
wherein are in predetermined positional relationship with the metallic conductive features.

10. The element as claimed in claim 9 wherein the metallic alignment elements are made from the same metal layer as the metallic conductive features.

11. The element as claimed in claim 10 wherein the metallic alignment elements and the metallic conductive features are formed by etching a metal layer in a common etching process.

12. The in-process element as claimed in claim 9 wherein the second area is arranged at outer boundaries of the first area.

13. An in-process assembly including an element as claimed in claim 9 and a carrier frame overlying a surface of the substrate in the second area, the carrier frame having first engagement features engaged with the metallic alignment elements.

14. An assembly as claimed in claim 13 wherein the carrier frame has second engagement features adapted to engage locating elements of a fixture, said second engagement features being in a predetermined positional relationship with the first locating features.

15. The in-process element according to claim 9, wherein the electrically conductive features include terminals.

16. The in-process element according to claim 15 wherein the terminals include pins projecting from a surface of the substrate.

17. The in-process element according to claim 9, wherein the metallic alignment elements include posts projecting from the surface of the substrate.

18. The in-process element according to claim 9, wherein the metallic alignment elements include ridges, at least some of the ridges being oriented in a different angle towards other ridges.

19. The in-process element according to claim 9, wherein the metallic alignment elements include posts, one post arranged in a corner of the substrate being longer than remaining posts.
